(19) United States
(12) Patent Application Publication
(10) Pub. No.: US 2006/0152228 A1
(43) Pub. Date: Jul. 13, 2006

(54) Microwave resonator, textile machine comprising such a resonator and dielectric for such a resonator

(76) Inventors: Ottmar Kovacs, Berching (DE); Wolfgang Gohler, Lenting (DE); Chikri Cherif, Ingolstadt (DE)

Correspondence Address: DORITY & MANNING, P.A., POST OFFICE BOX 1449, GREENVILLE, SC, 29602-1449, US

(21) Appl. No.: 10/545,141

(22) PCT Filed: Feb. 13, 2004
(86) PCT No.: PCT/EP04/01352

§ 371 Date: Aug. 10, 2005

(30) Foreign Application Priority Data
Feb. 13, 2003 (DE) 10306217.3

(51) Int. Cl. G01R 27/32

(52) U.S. Cl. 324/635

(57) ABSTRACT

A microwave resonator for or on a textile machine, in particular a carding, drawing or combing machine is disclosed, for connection to a measuring device for measuring the thickness and or the dampness of fibre material (FB), continuously passing through the resonator chamber (31; 331). Said microwave resonator is characterised in that at least partly at least one non-conducting dielectric (303, 307; 460; 460a, 460b) is provided in the resonator (30), the dielectric constant of which remains essentially unchanged during temperature variations which are normal during machine operation. A corresponding textile machine and a dielectric for a microwave resonator are further disclosed.

The invention concerns a microwave resonator for connection to a measuring apparatus for the measurement of band thickness and/or the water content of a fiber material being continually transported through the said resonator, and concerns also a textile machine with a microwave resonator of this kind.

The measurement of fiber properties in the textile industry is, without question, basic to the production of high value textiles. Thus, for example, the measurement of fiber band thicknesses is essential, especially for the purpose of excluding irregularities in fiber bands being transported through one or more spinning machines. Likewise, the fulfillment of the best aims of quality control of material being drafted and equipment for measurement of said irregularities at the output end of a machine is highly to be desired. Accurately determined values of fiber band thickness (the terms “band cross-section” or “band bulk” are also commonly used) are brought into use, not only for quality control, but all for shut-downs of the machine, in a case where a specified threshold value of the band thickness has been overstepped. At such a stillstand time, no high value product can be produced.

Up to the present time, mechanically touch-oriented sensors have been installed for the determination of the thickness of the fiber band. Also, capacity based instruments are known in the industry. A new method for the measurement of fiber band thickness, contrary to the above, introduces the use of microwaves. In this case, microwave radiation is produced by a microwave generator, the frequency of which could be regulated, within certain limits, by a computer based controller. The said waves could also be purposely activated in a resonation space of a microwave resonator, through which resonator the fiber material was continually being transported. The properties of fiber material include thickness, consistency, geometry and water-content of the band. According to these properties, a given band emits a characteristic microwave frequency reflected in a resonance signal, which, when de-activated by a computer, allows the evaluation of the band properties. A method of this type, for example, is described in EP 0468023 in regard to other applications. The therein provided disclosures are fully recognized and are included here. The advantages of such a measurement procedure by microwaves are especially to be found therein, in that a precise, contact-free inspection of fiber material has been enabled. Mechanical disturbances of the band as well as inaccuracies in measurement because of inertial qualities of the mechanical elements are excluded by the said microwave procedure.

Experience has shown, however, that diverse problems exist in regard to the coaction of a resonator with the fiber materials passing therethrough. On this account, for example, it is known that during an absence of fiber material from the resonator space—that is, when the machine runs out of material, or while a band jamming is removed—the empty resonance space frequency declines as time goes on, due to a drop in its temperature. Upon a renewed introduction of fiber material into the resonator, the microwave effect has become inactive, and must be re-activated. Other problems concern swings of the resonance frequencies during operation. These, however, do not arise from characteristics of fiber material.

Thus it is the purpose of the invention, to improve the microwave resonator for the measurement of thickness, consistency, bulk and/or water content of fiber material which is being transported therethrough.

This purpose is achieved in a microwave resonator of the type described in the opening passages by means of the features of claim 1. Further this purpose is also achieved by a textile machine with a resonator of the described kind. In another aspect, this purpose is achieved by a dielectric for such a resonator.

The invented resonator possesses at least one non-electrically conducting dielectric, the dielectrical-constant of which remains predominately unchanged during temperature variations. If the temperature of the an emptied resonator space drops, then the empty resonance frequency scarcely alters, so that, upon the reintroduction of fiber material no retuning of the resonator is necessary. A renewed calibration of the resonator, under these circumstances, becomes superfluous.

Advantageously, the dielectrical constant of the at least one dielectric lies at a value of less than 12, in accord with the normal operating condition of the textile machines.

It is particularly to advantage in this connection, if the dielectric does not substantially ad/absorb moisture. A guide line in this direction would be, for example, a moisture intake of not more then 0.1%. Many materials, especially plastics, pick up moisture as temperature increases, with the result, that the resonance frequency exhibits falsified results, due to the said increase of moisture. By means of a selection of an appropriate material, this falsification can be prevented.

Advantageously, a dielectric is at least to be wear resistant, in order to counter the abrasion of its contact with fiber.

Further it is favorable, if the selected dielectric does not deform during temperature swings. Such deformations result in disturbing influences upon the resonance frequency. These deformations can be repressed by the choice of appropriate materials. Substances with small coefficients of heat expansion could be, for example, steels of a high nickel content, such as Ni 36 steel such as Invar® steel.

Advantageous materials for the at least one dielectric would be ceramics, polycarbonates, or a composition material, the latter especially when the embedment is a ceramic substance. Further as a binding material, TMM®, of the American firm of Rogers, has proved itself in operation. This material is a hydrocarbon-ceramic composition material with a very satisfactory temperature stability and, even when subjected to temperature swings, maintains a very stable dielectric constant.

In an approved embodiment of the invention, the at least one dielectric part of the resonator space is covered, in order, that in this way the infiltration of dust, or free fibers into this space can be prevented. Such infiltration would disturb the measurements by shifting the resonance.

Advantageously, in the resonator, the at least one dielectric is located along the path of transport of the fiber material. For example, the at least one dielectric is enclosed by a web or a bridge in a passage between two wall sections of the resonator. This web can extend itself from the resonator inlet to the outlet of the same.

In an advantageous embodiment for the carrying out of the stated purpose, the dielectric can be fashioned in the form of a plate, whereby the fiber material is guided to pass along this plate (or plates) as it is transported through the resonator. The fiber material, in this case, is in direct contact with the dielectric. In this case, it is of advantage, if the at least one dielectric extends itself from the resonator inlet to the outlet of the same so that assurance can be given, that the space of the resonator interior is fully isolated from fiber material, because, first, a sealed throughput path for the said fiber material is provided and second, an appropriate arrangement of the at least one plate—that is, the at least one dielectric—is arranged for.

In another advantageous embodiment of the present invention, the microwave resonator is placed in essentially two half cylinders, arranged to be parallel to one another, and between which the fiber material is transported transverse to the longitudinal axes of the half cylinders. In more detail, in this case the resonator walls are formed by the semi-cylindrical shells, while flat surfaces thereof, placed diametrically between the half cylinders, face one another in parallel and thus form plate shaped dielectrics, between which the fiber material passes.

Alternative to, or in addition to the above, a dielectric can placed on at least one of the flat wall sections which enclose the resonator space, which arrangement assures that the fiber material does not come into contact with this wall section. The dielectric can, in this case, be installed on the appropriate resonator inner wall by means of variously adaptable methods, namely in the form of essentially rigid plates, which, as needed, can be designed to fit the geometry of the wall. Alternatively to the said rigid plate method, a dielectrically active coating can be applied by an evaporation method, or by coating in a liquid condition with subsequent drying, such as in an oven.

In a further alternative, the at least one dielectric is so applied, that at least one partial volume of the resonator space is filled. In a special formation, in this case, the material essentially occupies the entire resonance space, with the exception of the transport path of the fiber material.

For the resonator walls, a material of low heat expansion is favorably selected, in order to avoid measurement errors due to temperature related deformation. An advantageous solution to this problem is the use of a steel of high nickel content, for instance, Ni 36 steel, or, for example, Invar® steel, which exhibits an appropriate, very low heat expansion coefficient. Since, in any case, microwave resonance fields are very difficult to establish, when the said Invar® steel is employed, in a preferred embodiment of the resonance space, the inner lining is finished with an easily applied, electrically conductive coating which, for example, is made from an oxygen-depleted copper composition. On this said copper coating would be superimposed, advantageously, a dielectric in accord with the invention. Preferably, this can be realized, in that at least one dielectric can be placed directly onto the conductive coating.

The mentioned ceramic composition agent, namely TMM®, or its equivalent, has the advantage, that its dielectric constant is essentially, not only constant (in the operational temperatures of 20 to 60° C.) but, besides this, is of a relatively small value. Since the microwave signal speed is dependent upon the dielectric constant, then a small dielectric constant means also a low signal speed and therewith a greater wave length in the signal. On this account, in a situation where resolution of a signal remains constant, the overall dimensioning of the resolution space can be selected to be less then would be the case in a choice of an at least one dielectric material having a larger dielectric constant. The same advantages obviously arise in the case of materials with characteristics similar to those of TMM®.

For the transport of fiber materials through the resonator space, as compared to a plate-shaped arrangement, an alternative dielectric placed on both end faces of an open guide tube can be employed, through which fiber material can be moved. Thus textile fibers cannot infiltrate into remaining part of the resonator space, which would demand, that from time to time, cleaning becomes necessary. This type of embodiment is, for example, preferred if principally a single fiber band is conducted through the resonator, since here the round, tube cross-section will match the round fiber band cross-section. Such a resonator, for example, can be installed on a drafting system or at the input end of a drawing frame, which receives the band coming from a forward located carding machine.

In an advantageous embodiment variant, the guide tube is, at least partially, designed to be conical, with its diameter decreasing in the direction of the fiber flow. That is to say, the said guide tube is somewhat funnel shaped in order to thicken the fiber material, at least to a certain extent, before it is delivered to an immediately subsequent calender roll-pair.

For the purpose of simplifying the introduction of the fiber material into the resonator, it is possible that the entry opening of the guide tube be widened, and thus again be somewhat conical, diminishing in diameter in the direction of fiber flow.

Since the guide tube is advantageously designed to be exchangeable, it becomes possible, for example, that in accord with the respective band fineness, a matching guide tube can be selected. In a better way, the evaluation of the deenergized microwave signal can be made to be compatible with the currently employed guide tube. A revised rework of the evaluation software can be dispensed with, if the dimensions of various guide tubes in the area of the microwave radiation are generally selected to be equal. This requires the selection of a correspondingly adapted geometry of the guide tube.

The present embodiment deals with a construction, wherein a guide tube penetrates the resonator space, which tube can be seen as an invented, dielectrically functioning tube, that is to say, the outside diameter of the individual tube remains equal for different inside diameters. In alternative embodiments, at least two tubes are provided as invented dielectrics, wherein an inside tube is slidingly inserted within an outer tube. The fiber material is, in this case, conducted through the inner tube. With such a design, it is also possible that likewise, various inner guide tubes of different inside diameters could be exchangeably placed within the advantageously same outer tube. The outer tube serves predominately for the reception of the inner tube and is favorably installed in the resonator in an appropriate manner, that is to say, with an outer annular fastening ring thereto attached. In the case of this embodiment, the precision of the resonance signal evaluation for the various inner tubes can be assured by recalibration of the evaluation software and/or by the use of inside tubes of the same dimension in the microwave propagation area.

Advantageously, the guide tube, on its downstream side, is coupled, or can be coupled, with a band funnel, so that this unit can assume a doubled function and yet have a minimum space-demand. In the case of a direct connection with one another, the band funnel can be slidingly inserted on the end of the tube, or screwed thereupon, or affixed by yet other means. Alternately, also a one-piece design of guide tube cum band funnel is possible. The band funnel runs the drafted fiber band into a compressing cross-sectional fissure between a subsequently located calender roll-pair, so that the extent of the free, fiber band path between the band funnel and the calender roll-pair is made as short as possible.

Advantageous developments are characterized by the features of the subordinate claims.

In the following, the invention is more closely described and explained with the aid of the drawing. There is shown in:

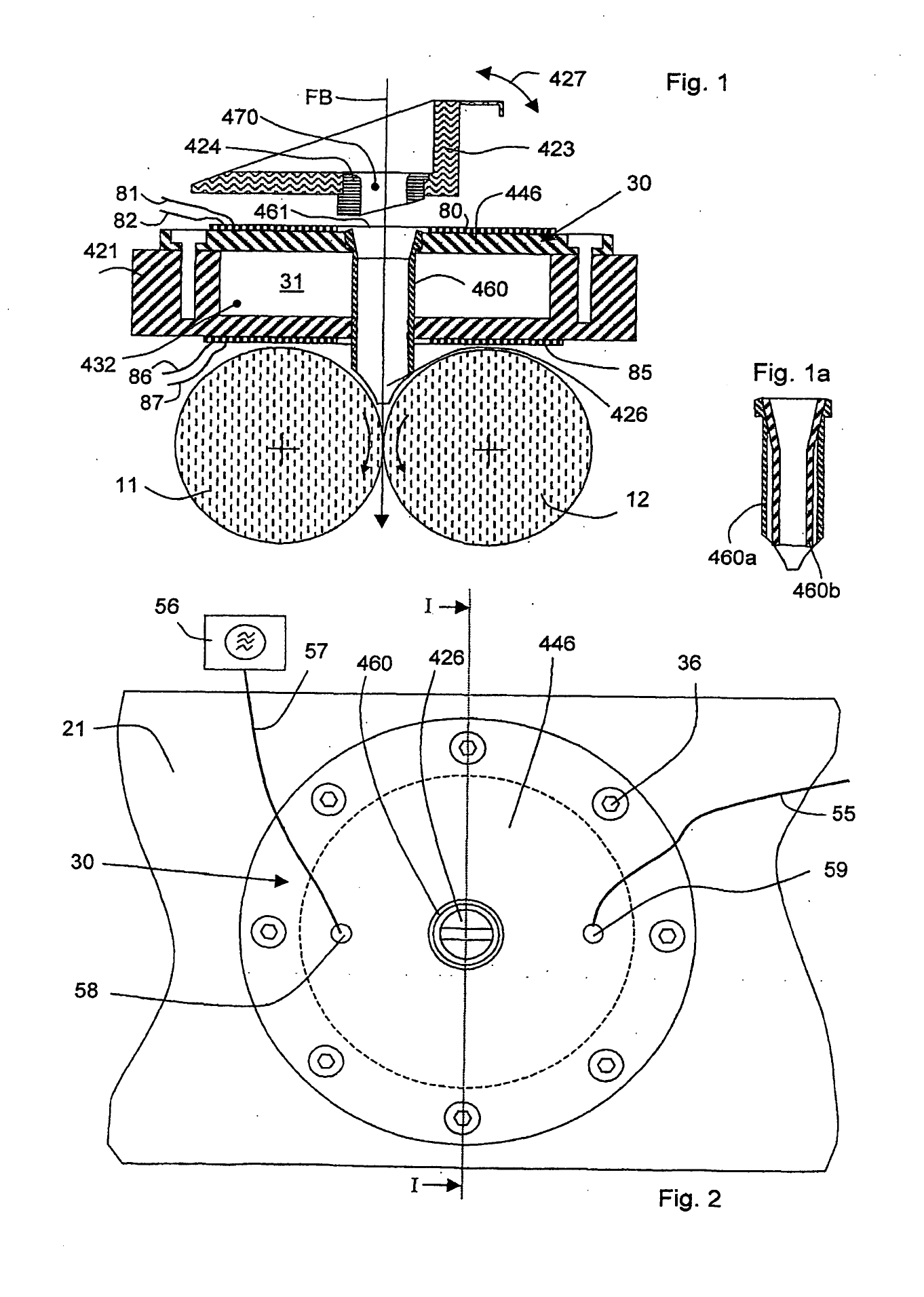

FIG. 1 a microwave resonator in accord with a first embodiment example, sectioned along I-I in accord with the FIG. 2,

FIG. 1a a sectioned detailed view of a special embodiment of two tubes, placed within one another and serving as dielectric means,

FIG. 2 the microwave resonator of FIG. 1 in plan view, (a material guide nozzle for loose woven fiber has been removed),

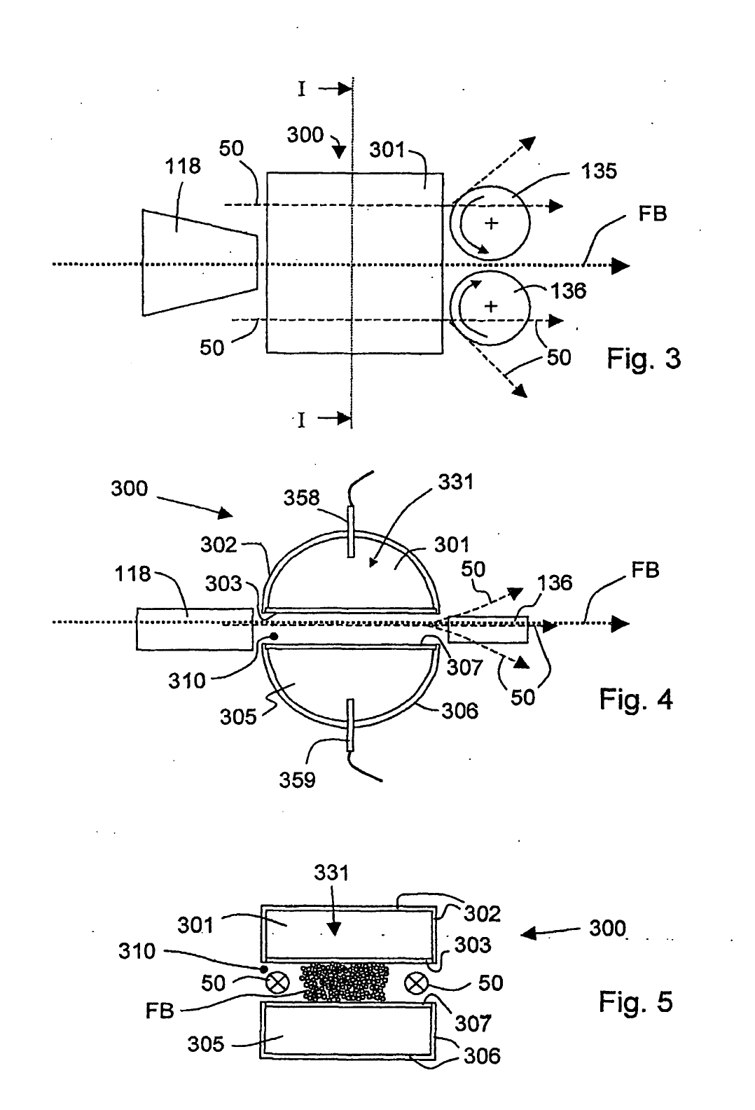

FIG. 3 a microwave resonator in accord with a second embodiment seen in plan view,

FIG. 4 a microwave resonator in accord with FIG. 3 in a sectioned profile view, (i.e., vertical section longitudinally made through the resonator), and

FIG. 5 the microwave resonator in accord with the FIGS. 3, 4 as seen from the back end. (section along I-I in accord with the FIG. 3)

In the FIGS. 1 and 2 is illustrated a first embodiment example of the invention, as seen, respectively, from the side in a central section and from above. A resonator 30 is placed in a plate-like carrier block 421. The carrier block 421 possesses, in this respect, a central recess 432, which, in the depicted embodiment, is in the form of a cylinder, as may be inferred from the top view of FIG. 2. On this recess 432 is set a wall element 446, which, as shown, is here designed as a flat, cylindrical disk. This wall element 446 has, circumferentially apportioned, screw holes 36a, which match aligned blind borings 36b in the said carrier block 421. As is presented in FIG. 2, it is possible, that into these borings 36a, 36b, which respectively possess female threading, hexagonal headed screws can be engaged, in order to affix the wall element 446 with the carrier block 21. The screws are not shown in FIG. 1. In an alternative embodiment, which is not illustrated, the wall element 446 can itself be fitted into a complementary top-side recess in the carrier block 21, so that the top of the wall element 446 is parallel to and in the same plane as the top of the carrier block 21 and is then screwed into this position.

The wall element 446 which has been set upon the recess 432, creates what becomes a resonator space 31 for the microwave resonator 30. Within this said microwave resonator 30, the microwaves can be energized with the aid of an activation element 58, and deactivated by a deactivator 59 as shown in FIG. 2. Both, rodlike activation/deactivation elements 58, 59 extend themselves through respective borings in the wall element 446 from the outside into the interior resonance space 31. The activation element 58 is connected by means of a cable 57 to a schematically indicated microwave generator 56, the frequency of which, can be varied with the aid of a (not shown) controller. The deactivator 59 is itself connected by a cable 55 to a (not shown) evaluation unit. The deactivator 59 receives the microwave signals which are formed in the resonator and conducts these to the evaluation unit, so that the said evaluation unit can plot the successive points of time and the thereto related signal widths. From these data, band thickness and/or bulk of fiber band which is currently passing through the resonator space can be determined.

In the recess 432 is to be found a dielectric 460, which has been designed essentially as a hollow, cylindrical tube 460, which has been made from a dielectric material. The through-put opening in the guide tube 460 aligns itself with a central penetrating opening of the wall element 446 as well as with a through opening in the carrier block 421. The fiber band FB, here designated simply as a dotted line, can thus be run linearly through the resonator space 31 directly into the clamping fissure between the immediately following calender roll-pair 11, 12.

The guide tube, which, in this case, is also the dielectric 460, consists of a material, the dielectric constant of which, in terms of normal machine operational temperature changes, namely between 20 and 60° C., remains essentially unchangeable. As a result of this, the empty resonance frequency of the resonator 30 scarcely changes during that period between the exit of the end of one fiber band until the entry of a new fiber band, regardless of the time taken. Consequently, no new calibration of the microwave sensors need be made.

Further, the material of the guide tube 460 is advantageously essentially wear resistant, and does not pickup moisture and does not distort itself during swings in temperature.

As materials, which fulfill the above requirements, applicable ceramics, polycarbonates, hydrocarbon-ceramic composition substances, and other composition mixes have proven themselves in service. These favorable properties are especially well met by a composition basically of a plastic with embedded ceramics which is marketed by the acronym TMM®.

The guide tube/dielectric 460, in accord with the embodiment shown in FIG. 1, possesses in the area of the wall element 446 a conical widening 461 and has further an annular collar. This collar, when the said guide tube 460 is inserted, makes a tight seal, abutting against a correspondingly stepped edge of a penetrative opening in the wall element 446. In this way, first, a secure placement of the guide tube 460 is assured in the resonator 30, and second, the guide tube 460 can be exchanged quickly and without difficulty. The opposing end face of the guide tube 460 is designed as a band funnel 426 with a nozzle-like termination. The said band funnel 426 is placed as close as possible to the fissure of compression between the calender roll-pair 11, 12.

The guide tube 460 can be exchanged in a simple way, in that the wall element 446 can be screwed free and taken away. In accord with the characteristics of the material and the drafting conditions, it is possible to use various inserts 460, which advantageously possess the same dimensioning in the microwave propagation area, so that a new calibration of the resonator is not necessary. Advantageously, in this case, the outside diameter of the current remains the same, although the inside diameter changes.

In an alternative embodiment, in FIG. 1a are shown at least two concentric tubes 460a and 460b, which are provided as invented dielectrics, whereby an inner tube, 460b is slidingly inserted in an outer tube 460a. The inner tube 460b serves as a guide tube for the fiber band. The outer tube 460a is principally for the holding of the said inner tube 460b and is advantageously affixed to the resonator, for example with its circumferential ring, as is shown in FIG. 1. In this way, it is possible, that in an optional manner, various guide tubes 460b with different inside diameters can be advantageously inserted into the same outer tube 460a, without the necessity of removing the said outer tube. Thus, the interior space of the resonator, even in a case of an exchange of the inner guide tube 460b is protected from the infiltration of harmful foreign bodies. The precision of the resonance evaluation for the various inner tubes 460b can be achieved, in the case of this embodiment, by a recalibration and/or by employing the same dimensioning for the dielectrics 460a and 460b.

As may be learned from FIG. 1, above the wall element 446 is placed a nozzle insert 424 for loose woven fiber material, which is held in place by a (not shown) centering pin. On the guide tube, i.e., on that side which is remote from the dielectric 460, is located the loose fiber insert 24, which is rounded on the circumferential rim, in order to assure a protected inlet of the fiber band FB into the guide tube 460. The loose fiber nozzle 423 is so linked onto the carrier block, that it can be pivoted in the direction of the double arrow 427, especially in a case of a loose fiber buildup jam at the nozzle 423. The linkages of the loose woven fiber nozzle 423 on the narrow side of the carrier block 421 are not shown.

On that side of the wall element 446, which is remote from the resonator 30, is placed a first, electrical heating foil 80, while on the oppositely situated, and outside of the carrier block 421 is a second heating foil 85. Both heating foils 80, 85 have, respectively, connection lines 81, 82 and 86, 87 which lead to a (not shown) heating source. The heat load is advantageously controlled and held, for example, at 35° C. For this are provided, advantageously, one or more temperature measuring apparatuses (not shown), which, for example, can be placed in one, possibly more, lateral borings in the carrier block 421, which borings reach to the resonator space 31. A thermal shell-like insulation, which encompasses the entire carrier block and has openings for the fiber material, can be provided for the prevention of the influence of temperature swings in the ambient neighborhood as well as serving as a repression of heat loss.

Additional, or alternative, measures for temperature stabilization can be found, in that the surrounding elements of the resonance space 31 are made out of a material with a low temperature expansion coefficient, this material being, for example, a steel of high nickel content, for instance, Invar®-Steel.

The interior wall of the resonator 30 can possess a conductive coating of, for example, oxygen deficient copper, since the Invar®-Steel of the wall element 446 and the carrier block 421 have only a very low electrical conductivity. Microwave resonances could not build themselves up to a sufficient signal strength without such a conductive coating. In order to repress a corrosion of the coating, onto the said coating is to be deposited a coating of, for example, gold or silver. Alternately, a ceramic or a composition material can be employed as a coating or as a covering. The resonator 30 with the dielectric formed from the guide tube 460 can advantageously, be placed following a drafting system. The loose wool fiber leaving the said drafting system is shaped into a band and subsequently conducted into the resonator 30. As an alternative to this, it is possible that the resonator 30 can be located between a carding machine and a drafting machine, whereby the fiber material exiting from the carding machine is to be transported without an intermediate stage in a can into the drafting system of the drafting machine.

In the FIGS. 3 to 5, is presented a microwave resonator 300—depicted without a microwave generator—with a forward located funnel 118 and calender roll-pairs 135, 136, wherein the calender roll-pair 135, 136 pulls at least one fiber band FB through the funnel 118 and the resonator 300. In the FIGS. 3 and 4, the at least one fiber band FB is designated principally by one dotted arrow. In FIG. 5, the fiber band 2 is presented in profile view as a combination of many individual fiber bands. If several fiber bands FB are transported through the resonator 300, then these lie advantageously beside one another, In the FIG. 5 the funnel 118 and the calender rolls 135 are not illustrated. Instead of the funnel shape 118, also other guide elements for bands could be employed, notably horizontally and/or vertically arranged displacement rods, which, for example, could have concave guide surfaces, in order to direct the at least one fiber band centrally into resonator 300. Further, it is possible that the calender roll pairs 135 can be repositioned about 90°, or any other optional angle from that shown.

The resonator 300 possesses two, separate, closed half-cylinders 301, 305, which are separated by an opening 310, whereby the outer walls 302, 306 of the half cylinders 301, 305 are made of metal. The inner walls 303, 307, which are proximal to the fiber band, are designed as dielectrics in the concept of this invention. The material for these plate shaped dielectrics 303, 307 consists of TMM® or another equivalent material. Reference should be made to the above given descriptions and explanations of the guide tube 460. The microwave resonance establishes itself in the resonance space between the walls 302 and 306.

The plate shaped dielectrics 303, 307 are, advantageously, designed to the exchangeable and hence, upon damage thereto, can be easily renewed.

The fiber material is passively conducted along the walls 303, 307, as seen in FIG. 5. Since the respective inner spaces of the half cylinders 301, 305 are closed against the ambient environment, no dust, fiber lint, or the like can infiltrate therein. Into these inner spaces, penetrate the activator 358 and the deactivator 359. For the sake of simplicity of the drawings, this penetration is shown only in FIG. 4.

In the direction of the fiber transport, it is advantageous if, on both sides of the fiber band(s) FB an air flow is caused to flow through the opening 310, which is indicated in FIGS. 3, 4 by dotted lines. In FIG. this air flow is designated by an “end view” of the departing air flow, namely, the conventional circle with an inside cross 50. The air flow 50, in one or more currents, can assume more than one function. First, this will care for a predominately uniform temperature within the opening 310, second prevent a surface accumulation of, in particular, fiber material on the inside walls 303, 307 of the half cylinders 301, 305, likewise hinder a deposit at the outlet of the resonator 300 or at the transition to the calender roll-pair 135, 136. Such deposits of unwanted material throw the resonator out of tuning and lead to errors in measurement.

Further, it is possible that the air stream 50 can be employed to achieve a desired temperature adjustment, especially on the resonator walls 302, 205. It is especially advantageous to use cooling air, in order that the resonator walls, to the greatest extent possible, can be kept at a constant temperature, this being somewhat lower than that of normal operation.

The described microwave resonators with the microwave generator can be installed, for example on a drawing frame with a controlled or uncontrolled drafting system. In the case of a controlled drafting system, one microwave sensor can be placed at the front, and another following the machine. The invention permits, likewise, installation without any limitations in carding and combing machines.

1. A microwave resonator for or on a textile machine, especially a machine for carding, drafting or combing, for connection to a measurement apparatus for the measurement of the thickness and/or the water content of fiber material (FB) which is continually being transported through the resonator space (31, 331) therein characterized, in that in the resonator (30), at least in areas, at least one electrical non- conducting dielectric (303, 307; 460; 460a, 460b) is provided, the dielectric constant of which remains essentially unchangeable at normal machine operational temperature variations.

2-25. (canceled)
